(19) United States
(12) Patent Application Publication
(10) Pub. No.: US 2006/0250870 A1
(43) Pub. Date: Nov. 9, 2006

(54) Semiconductor memory device

(75) Inventor: Jin Hee Cho, Chungcheongbuk-do (KR)

Correspondence Address: HELLER EHRMAN WHITE & MCAULIFFE LLP, 1717 RHODE ISLAND AVE, NW, WASHINGTON, DC, 20036-3001, US

(73) Assignee: Hynix Semiconductor Inc., Gyeonggi-do (KR)

(21) Appl. No.: 11/139,444

(22) Filed: May 31, 2005

(30) Foreign Application Priority Data
May 9, 2005 (KR) 10-2005-0038389

(51) Int. Cl. G11C 7/00

(52) U.S. Cl. 365/205

(57) ABSTRACT

A semiconductor memory device is provided with a plurality of sense amplifiers adapted and configured to sense and amplify data stored in memory cells, a sense amplifier control unit adapted and configured to generate a driving voltage for driving the plurality of sense amplifiers, and a identification unit adapted and configured to generate an bit organization identification signal which represents a I/O structure and output the signal to the sense amplifier control unit. Here, the sense amplifier control unit regulates a level of the driving voltage in response to the bit organization identification signal. The semiconductor memory device supplies an optimized power source in each mode, thereby reducing current consumption and improving operating characteristics.

### BACKGROUND OF THE INVENTION

1. Field of the Invention

The present invention generally relates to a refresh circuit of a semiconductor memory device, and more specifically, to a technology of supplying an optimized power in each mode to reduce current consumption generated by a difference between driving capacity and supply capacity and improve operating characteristics.

2. Description of the Related Art

In DRAMs, as the degree of integration increases, the operating speed is speeded up. Recently, the DRAM has been developed through a DDR1 SDRAM into a DDR2 SDRAM.

In case of the DDR1, the same number of word lines is enabled in an active mode at the same time regardless of an IO structure (X4, X8, X16) in the same density. However, in case of the DDR2, the number of word lines enabled by each structure in the active mode is different even in the same density at a device of over 512M on JEDEC Spec.

FIGS. 1a and 1b are timing diagrams illustrating the conventional SDRAM. FIG. 1a is a timing diagram in case of a X4/X8 mode, and FIG. 1b is a timing diagram in case of a X16 mode.

In the conventional SDRAM and the DDR1 SDRAM has the same density, when an active command is enabled regardless of X4/X8/X16 bit organization, the same number of word lines is identical in each bank.

However, in case of the DDR2 SDRAM which has the density of over 512 Mb, the active command is enabled in each bit organization of X4/X8 and X16, so that the number of word lines in each bank is not identical. The number of word lines is two times larger in the X16 mode than in the X4/X8 modes. Since an I/O line is selected in response to an address A13 in the X4/X8 modes of the DDR2, the DDR2 is configured to select one from two groups of 8K word lines in response to the address A13.

Generally, when a DRAM is designed, each of X4/X8/X16 bit organizations is designed by the same mask. Additionally, the bit organizations are distinguished by metal mask option or bonding option.

In the X4/X8 modes, when an activation period D1 of the first high level control signal SAP1 is set as shown in FIG. 3a, a word line in each bank is activated, so that a level of a bit line is sufficiently amplified to the second core voltage level Vcore2.

In the X16 mode, when the activation period D1 of the first high level control signal SAP1 is set as shown in FIG. 3b, two word lines in each bank are activated, so that the level of the bit line is not sufficiently amplified. Specifically, when the DDR2 is operated at a minimum RAS cycle operating timing tRCmin, a difference of about ΔV between the bit line level and the second core voltage Vcore2 is generated at a precharge mode to degrade a refresh characteristic.

When the operating period D1 of the first high level control signal SAP1 becomes longer based on the X16 mode, the amplification of the bit line becomes rapid by the first core voltage Vcore1 which is a sense amplifier power in the X4/X8 modes, thereby causing excessive current.

### SUMMARY OF THE INVENTION

Various embodiments of the present invention are directed at automatically selecting a mode depending on bonding option in package at each mode, thereby differently controlling an activation period of a sense amplifier control signal.

According to one embodiment of the present invention, a semiconductor memory device is provided with a plurality of sense amplifiers adapted and configured to sense and amplify data stored in memory cells, a sense amplifier control unit adapted and configured to generate a driving voltage for driving the plurality of sense amplifiers, and a identification unit adapted and configured to generate an bit organization identification signal which represents a I/O structure and output the signal to the sense amplifier control unit. Here, the sense amplifier control unit regulates a level of the driving voltage in response to the bit organization identification signal.

### BRIEF DESCRIPTION OF THE DRAWINGS

Other aspects and advantages of the present invention will become apparent upon reading the following detailed description and upon reference to the drawings in which:

FIGS. 1a and 1b are timing diagrams illustrating the conventional SDRAM;

FIG. 2 is a block diagram illustrating a SDRAM according to an embodiment of the present invention;

FIG. 3 is a circuit diagram illustrating a sense amplifier control unit of FIG. 2;

FIG. 4 is a circuit diagram illustrating a bonding option unit for generating an bit organization identification signal SORGC; and

FIGS. 5a and 5b are timing diagrams illustrating the operation of the sense amplifier control unit of FIG. 3.

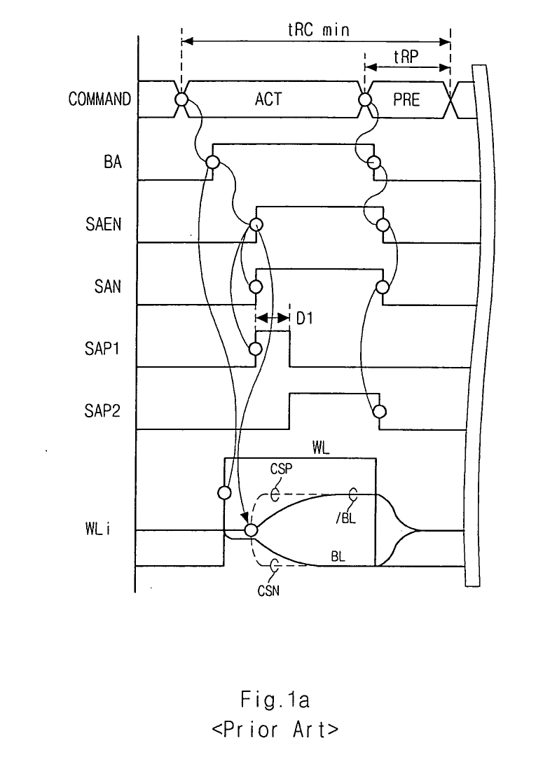

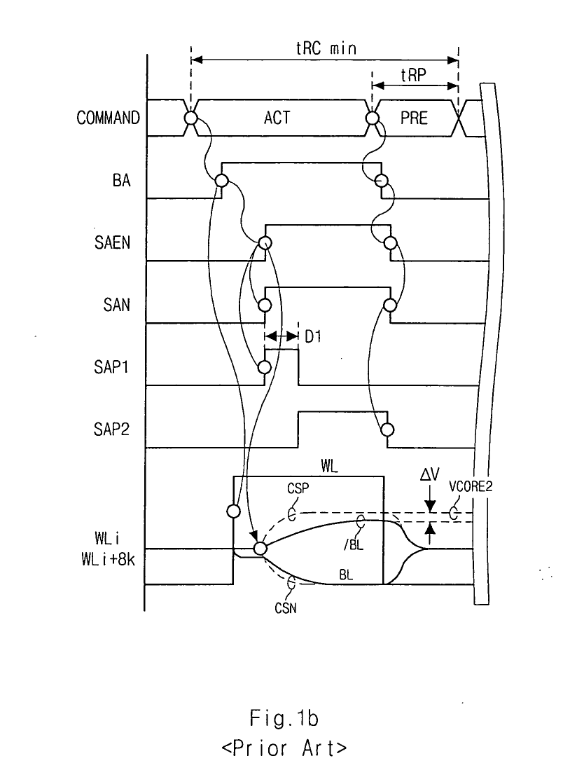

### DETAILED DESCRIPTION OF THE EXEMPLARY EMBODIMENTS

The present invention will be described in detail with reference to the accompanying drawings. Wherever possible, the same reference numbers will be used throughout the drawings to refer to the same or like part.

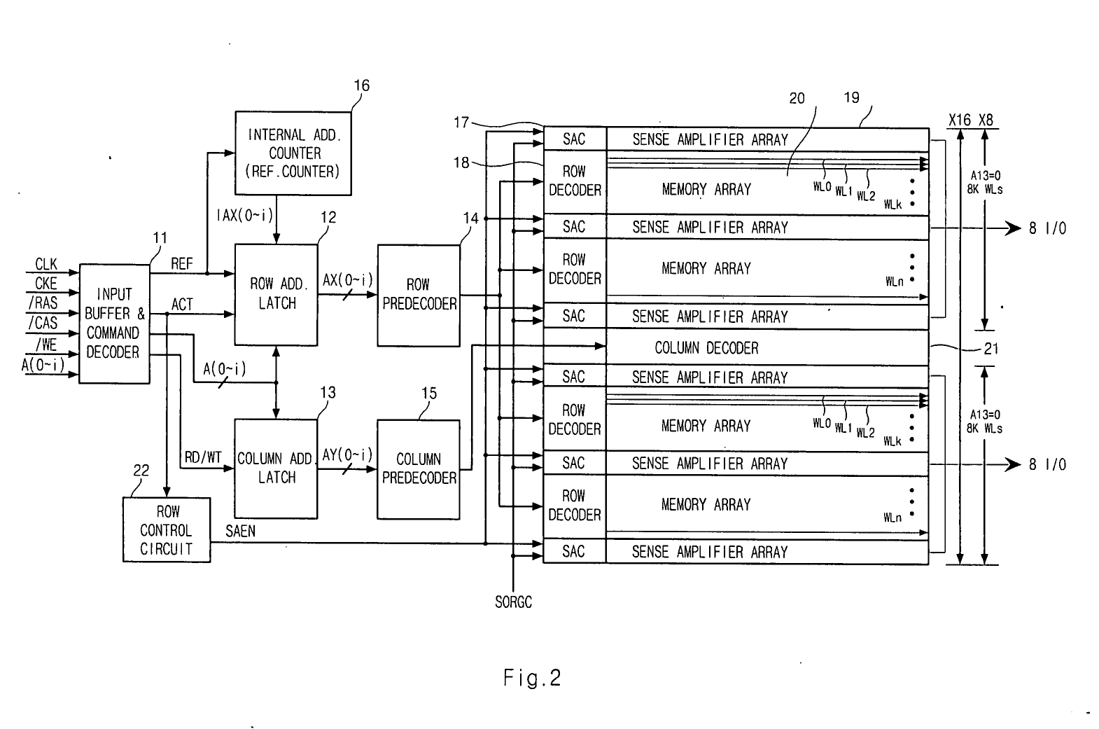

A SDRAM according to an embodiment of the present invention is shown in the diagram of FIG. 2.

The SDRAM comprises an input buffer & command decoder 11, a row address latch 12, a column address latch 13, a row predecoder 14, a column predecoder 15, an internal address counter 16, a sense amplifier control unit 17, a row decoder 18, a sense amplifier array 19, a memory array 20, a column decoder 21 and a row control circuit 22.

The input buffer and command decoder 11 receives an address and a command signal from an external unit to generate an operating signal.

The row address latch 12 latches a row address in response to a bank active command.

The column address latch 13 latches a column address in response to a read and write command.

The row predecoder 14 predecodes an address AX(0˜i) outputted from the row address latch 12.

The column predecoder 15 predecodes an address AY(0˜i) outputted from the column address latch 13.

The internal address counter 16 generates an internal address IAX(0˜i) for performing a refresh operation.

The sense amplifier control unit 17 controls operations of the sense amplifiers of the sense amplifier array 19.

The row decoder 18 selects a corresponding row (word line) in response to an address outputted from the row predecoder 14.

The column decoder 21 selects a corresponding column (bit line) in response to an address outputted from the column predecoder 15.

The row control unit 22 outputs a sense amplifier enable signal SAEN for enabling sense amplifiers of the sense amplifier array 19 to the sense amplifier control unit 17 in response to a bank active command ACT.

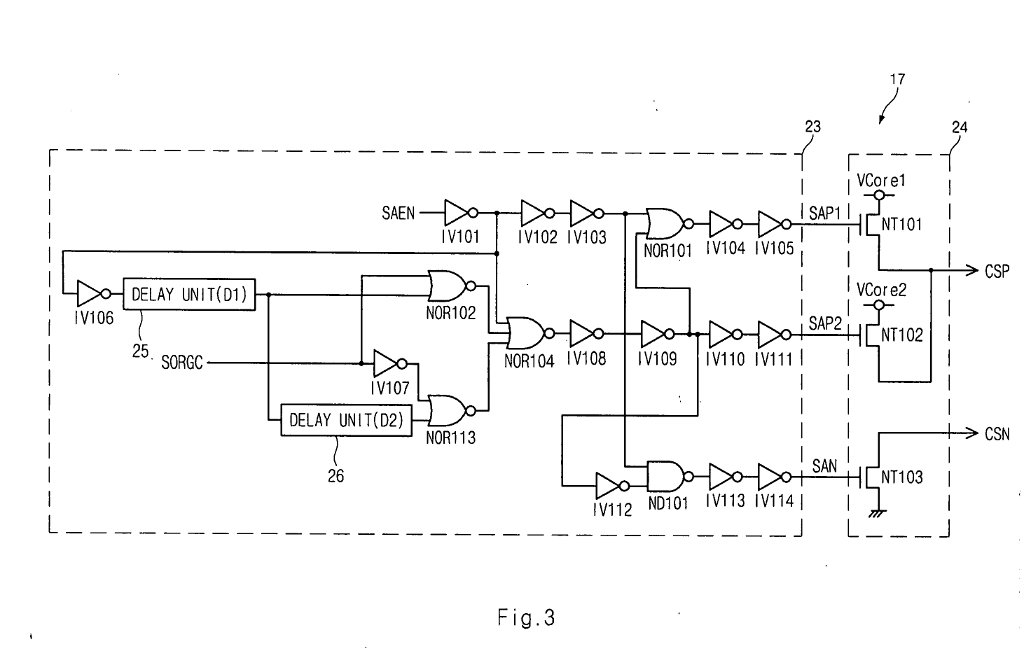

FIG. 3 is a circuit diagram illustrating the sense amplifier control unit 17 of FIG. 2.

The sense amplifier control unit 17 comprises a signal generating unit 23 adapted and configured to generate sense amplifier control signals and a driving unit 24 adapted and configured to drive sense amplifier control voltages in response to sense amplifier control signals.

The signal generating unit 23 comprises inverters IV101˜IV114, NOR gates NOR101˜NOR104, a NAND gate ND101, and delay units 25 and 26.

In X4/X8 modes, an bit organization identification signal SORGC becomes ‘low’. When the sense amplifier enable signal SAEN is enabled, during a delay time D1 of the first delay unit 29, the first high level control signal SAP1 becomes ‘high’ and a second high level enable signal SAP2 becomes ‘low’. Here, a low level control signal SAN is maintained at a high level.

In a X16 mode, the bit organization identification signal SORGC becomes ‘high’. When the sense amplifier enable signal SAEN is enabled, during a time obtained by adding the delay time D1 of the first delay unit 25 to a delay time D2 of the second delay unit 26, the first high level control signal SAP1 becomes ‘high’ and the second high level enable signal SAP2 becomes ‘low’. Here, the low level control signal SAN is maintained at a high level.

The level of the bit organization identification signal SORGC is determined depending on states of signals VBOP1/VBOP2 inputted from external control pins.

The driving unit 24 comprises a first NMOS transistor NT101, a second NMOS transistor NT102 and a NMOS transistor NT103. The first NMOS transistors NT101 is adapted and configured to drive a first core voltage Vcore1 in response to the first high level control signal SAP1 to output a high level driving voltage CSP. The second NMOS transistor NT102 is adapted and configured to drive a second core voltage Vcore2 in response to a second high level control signal SAP2 to output the high level driving voltage CSP. The NMOS transistor NT103 is adapted and configured to drive a ground voltage in response to the low level control signal SAN to output the low level driving voltage CSN. Here, the first core voltage Vcore1 is higher than the second core voltage Vcore2.

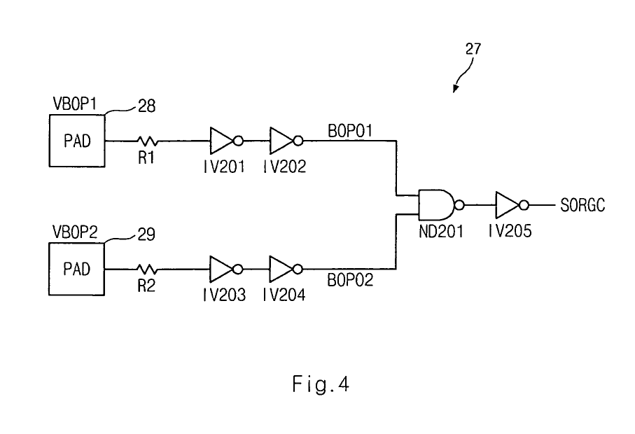

FIG. 4 is a circuit diagram illustrating a bonding option unit 27 for generating an bit organization identification signal SORGC.

The bonding option unit 27 comprises pads 28, 29 for receiving external control signals VBOP1 and VBOP2, load resistors R1 and R2, inverters IV201˜IV205 and a NAND gate ND201.

The control signals VBOP1 and VBOP2 inputted through the pads 28, 29 are stabilized through the load resistors R1 and R2 and the inverters IV201˜IV204.

Stabilized control signals BOPO1 and BOPO2 are combined through the NAND gate ND201 and the inverter IV205 to generate the bit organization identification signal SORGC.

Here, the level of the bit organization identification signal SORGC is determined depending on states of the external control signals VBOP1 and VBOP2.

Table 1 represents relationships between levels of the external control signals VBOP1 and VBOP2 and the level of the bit organization identification signal SORGC.

TABLE 1

| VBOP1 | VBOP2 | BOPO1 | BOPO2 | SORGC | Bit organization |
|---|---|---|---|---|---|
| L | L | L | L | L | — |
| H | L | H | L | L | ×4 mode |
| L | H | L | H | L | ×8 mode |
| H | H | H | H | H | ×16 mode |

The generation process of the bit organization identification signal SORGC is explained with reference to FIG. 4 and Table 1.

First, in the X4/X8 modes, the external control signals VBOP1 and VBOP2 are applied at different levels. That is, when the first external control signal VBOP1 is ‘high’ and the second external control signal VBOP2 is ‘low’, the bit organization identification signal SORGC is generated at a low level to represent the X4 mode. When the first external control signal VBOP1 is ‘low’ and the second external control signal VBOP2 is ‘high’, the bit organization identification signal SORGC is generated at the low level to represents the X8 mode.

Meanwhile, in the X16 mode, the external control signals VBOP1 and VBOP2 become ‘high’, so that the bit organization identification signal SORGC is generated at a high level to represent the X16 mode.

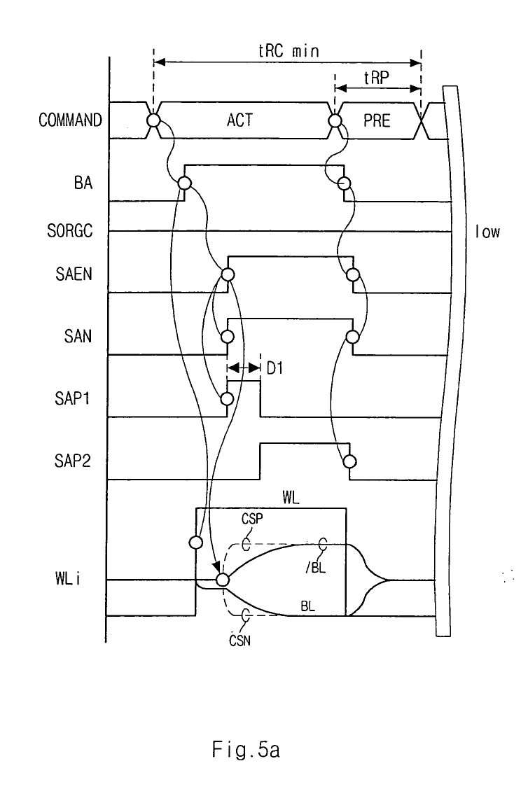

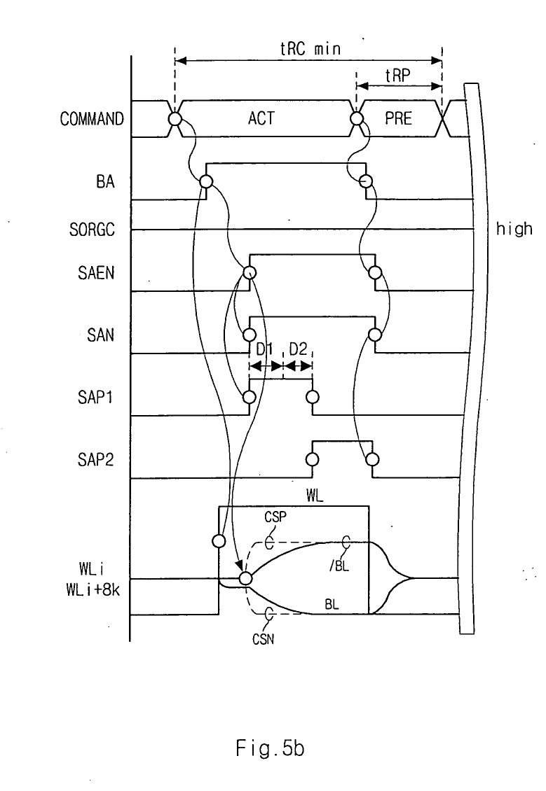

FIGS. 5a and 5b are timing diagrams illustrating the operation of the sense amplifier control unit 17 of FIG. 3. FIG. 5a shows the operation in the X4/X8 modes, and FIG. 5b shows the operation in the X16 mode.

In the X4/X8 modes as shown in FIG. 5a, when a bank active signal BA is activated in response to an active command ACT, the sense amplifier enable signal SAEN is activated.

When the bit organization identification signal SORGC becomes ‘low’ and the sense amplifier enable signal SAEN is activated, the first high level control signal SAP1 is activated to a high level for the delay time D1 of the first delay unit 25.

When the first high level control signal SAP1 becomes ‘high’, the high level driving voltage CSP is driven to the first core voltage Vcore1.

When the first high level control signal SAP1 becomes ‘low’, the second high level control signal SAP2 is activated to a high level.

When the second high level control signal SAP2 becomes ‘high’, the high level driving voltage CSP is driven to the second core voltage Vcore2 which is lower than the first core voltage Vcore1.

Here, the low level control signal SAN is activated while the sense amplifier enable signal SAEN is activated.

When the low level control signal SAN becomes ‘high’, the low level driving voltage CSN is driven to the ground voltage.

Meanwhile, in the mode X16 as shown in FIG. 5b, when the bank active signal BA is activated in response to the active command ACT, the sense amplifier enable signal SAEN is activated.

When the bit organization identification signal SORGC becomes ‘high’ and the sense amplifier enable signal SAEN is activated, the first high level control signal SAP1 is activated to the high level during the delay time D1+D2 of the first delay unit 25 and the second delay unit 26.

When the first high level control signal SAP1 becomes ‘high’, the high level driving voltage CSP is driven to the first core voltage Vcore1.

When the first high level control signal SAP1 becomes ‘low’, the second high level control signal SAP2 becomes activated to the high level.

When the second high level control signal SAP2 becomes ‘high’, the high level driving voltage CSP is driven to the second core voltage Vcore2 which is lower than the first core voltage Vcore1.

Here, the low level control signal SAN is activated to the high level while the sense amplifier enable signal SAEN is activated.

When the low level control signal SAN becomes ‘high’, the low level driving voltage CSN is driven to the ground voltage.

In other words, in the X4/X8 modes, the bit organization identification signal SORGC becomes ‘high’ by bonding option so that two word lines in each bank may be enabled at an active mode. As a result, the first high level control signal SAP1 is activated for a period obtained by adding the delay times D1+D2 of the first delay unit 25 and the second delay unit 26.

Although the state of the bit organization identification signal SORGC is determined by the bonding option in the above-described embodiment, the state of the bit organization identification signal SORGC may be determined by fuse option, that is, by programming a plurality of fuses if necessary.

As described above, a semiconductor memory device according to an embodiment of the present invention automatically controls a sense amplifier driving voltage depending on bonding option in each bit organization at the same density to optimize current consumption.

Additionally, the semiconductor memory device according to an embodiment of the present invention controls a sense amplifier driving voltage depending on bonding option in each bit organization at the same density to improve operating characteristics.

The foregoing description of various embodiments of the invention has been presented for purposes of illustrating and description. It is not intended to be exhaustive or to limit the invention to the precise form disclosed, and modifications and variations are possible in light of the above teachings or may be acquired from practice of the invention. Thus, the embodiments were chosen and described in order to explain the principles of the invention and its practical application to enable one skilled in the art to utilize the invention in various embodiments and with various modifications as are suited to the particular use contemplated.

What is claimed is:

1. A semiconductor memory device comprising:
a plurality of sense amplifiers adapted and configured to sense and amplify memory cell data;
a sense amplifier control unit adapted and configured to generate a driving voltage for driving the plurality of sense amplifiers; and
a identification unit adapted and configured to generate an bit organization identification signal which represents a I/O structure and output the signal to the sense amplifier control unit, wherein the sense amplifier control unit regulates a level of the driving voltage in response to the bit organization identification signal.

2. The semiconductor memory device according to claim 1, wherein the sense amplifier control unit comprises:
a level regulating unit adapted and configured to regulate the level of the driving voltage; and
a driving unit adapted and configured to drive the driving voltage by a plurality of power voltages in response to states of control signals outputted from the level regulating unit.

3. The semiconductor memory device according to claim 2, wherein the level regulating unit comprises:
a first signal generating unit adapted and configured to generate a first high level control signal for boosting the level of the driving voltage;
a second signal generating unit adapted and configured to generate a second high level control signal for boosting the level of the driving voltage; and
a third signal generating unit adapted and configured to generate a third high level control signal for lowering the level of the driving voltage.

4. The semiconductor memory device according to claim 3, wherein the driving unit comprises:
a first driving unit adapted and configured to drive the driving voltage to a first high level power voltage of the plurality of power voltages in response to the first high level control signal;
a second driving unit adapted and configured to drive the driving voltage to a second high level power voltage which is lower than the first high level power voltage of the plurality of power voltages in response to the second high level control signal; and
a third driving unit adapted and configured to drive the driving voltage to a ground voltage of the plurality of power voltages in response to the lower level control signal.

5. The semiconductor memory device according to claim 4, wherein the first signal generating unit comprises a delay unit adapted and configured to regulate an activation period of the first high level signal in response to the bit organization identification signal.

6. The semiconductor memory device according to claim 5, wherein the delay unit comprises:
a plurality of delay units; and
a logic unit adapted and configured to selectively transmit output signals from the plurality of delay units in response to the bit organization identification signal.

7. The semiconductor memory device according to claim 1, wherein the bit organization identification signal is generated by bonding option.

8. The semiconductor memory device according to claim 7, wherein the identification unit comprises a logic unit for determining a state of the bit organization identification signal in response to states of signals inputted from external pads.

9. The semiconductor memory device according to claim 8, wherein the identification unit further comprises a stabilization unit adapted and configured to stabilize sates of signals inputted from the external pads.

10. The semiconductor memory device according to claim 1, wherein the bit organization identification signal is generated by fuse option.

11. The semiconductor memory device according to claim 10, wherein the identification unit comprises a logic unit adapted and configured to determine a state of the bit organization identification signal in response to program states of a plurality of fuses.
